(19) United States
(12) Patent Application Publication
(10) Pub. No.: US 2014/0347090 A1
(43) Pub. Date: Nov. 27, 2014

(54) SYSTEM AND METHOD FOR TESTING LAYOUT OF POWER PIN OF INTEGRATED CHIP ON PRINTED CIRCUIT BOARD

(71) Applicants: HON HAI PRECISION INDUSTRY CO., LTD., New Taipei (TW); HONG FU JIN PRECISION INDUSTRY (ShenZhen) CO., LTD ., Shenzhen (CN)

(72) Inventor: GUANG-FENG OU, Shenzhen (CN)

(73) Assignees: HON HAI PRECISION INDUSTRY CO., LTD., New Taipei (TW); HONG FU JIN PRECISION INDUSTRY (ShenZhen) CO., LTD ., Shenzhen (CN)

(21) Appl. No.: 14/108,983

(22) Filed: Dec. 17, 2013

(30) Foreign Application Priority Data
May 21, 2013 (CN) 2013101882743

(51) Int. Cl. G01R 31/28

(52) U.S. Cl. CPC G01R 31/2801
USPC 324/763.01

(57) ABSTRACT

A testing system includes a layout information obtaining module, a first power pin sorting module, a transmission line sorting module, a power pin filtering module, a distance calculating module, a comparing module, and a report generating module. The layout information obtaining module obtains layout information. The first power pin sorting module sorts a power pin from a plurality of pins of a IC. The transmission line sorting module sorts transmission lines. The power pin filtering module filters power pins from a plurality of pins of capacities in same transmission line. The distance calculating module calculates distances between the power pin of the IC and each of the power pins of the capacities. The comparing module compares each of the distances with a threshold distance. The report generating module generates a testing report to depict whether or not the sorted power pins of the IC are qualified.

### BACKGROUND

1. Technical Field

The present disclosure relates to a system and a method for testing a layout of power pins of integrated chips on a printed circuit board.

2. Description of Related Art

A printed circuit board mechanically supports and electrically connects electronic components. Power pins of the integrated chips (ICs) are supplied with a steady direct current (DC) power, such as 5V, 3V, 1.8V, for example. The power pins are usually connected to a power source layer of the printed circuit board. However, the power source layer is located in an interior of the printed circuit board, and the electronic components are usually mounted on an outer surface of the printed circuit board. Therefore, a plurality of capacitors are defined in the printed circuit board to connect the power pins to the plurality of capacitors However, if a transmission line between the power pin and each of capacitor is too short, a strong inference signal will be generated, which interferes with power supplied to the ICs. Thus, a layout of the printed circuit board needs to be tested. However, existing testing technology depends heavily on human experience and judgment, which results in a low accuracy and a low efficiency.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of one embodiment of a computer device suitable for testing a layout of power pins of chipsets on a circuit board.

FIG. 2 is a block diagram of a testing system for testing a layout of power pins of chipsets on a circuit board.

FIG. 3 is a flow chart showing one embodiment of testing a layout of power pins of chipsets on a circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

In general, the word “module,” as used herein, refers to logic embodied in hardware or firmware, or to a collection of software instructions, written in a programming language such as Java, C, or assembly. One or more software instructions in the modules may be embedded in firmware, such as in an erasable-programmable read-only memory (EPROM). The modules described herein may be implemented as either software and/or hardware modules and may be stored in any type of non-transitory computer-readable medium or other storage device. Some non-limiting examples of non-transitory computer-readable media are compact discs (CDs), digital versatile discs (DVDs), Blu-Ray discs, Flash memory, and hard disk drives.

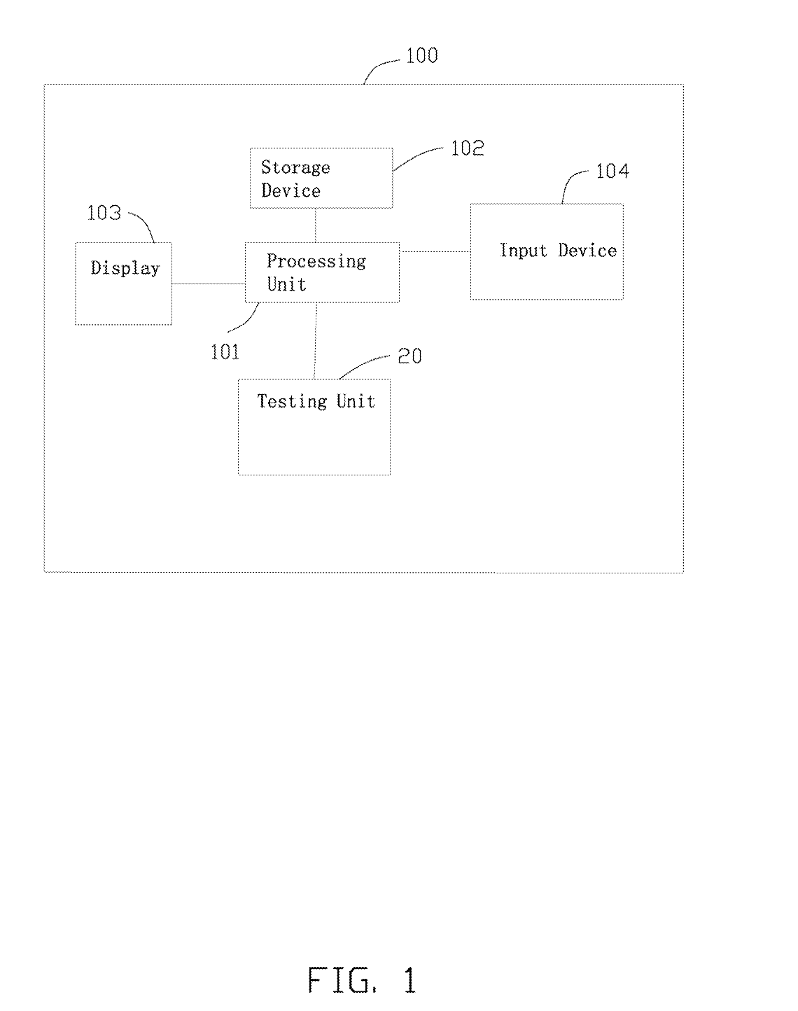

FIG. 1 shows one embodiment of a system 100 includes a processing unit 101, a storage device 102, a display 103, an input device 104 and a testing unit 20. The system 100 may be a host computer, a server computer, or a tablet computer, for example.

The processing unit 101 is coupled to the storage device 102, the display 103, the input device 104, and the EMI testing unit 20. The processing unit 101 may include one or more processors that provide the processing capability to execute the operating system, programs, user and application interfaces. The testing unit 20 is executable by the processing unit 101, and is configured for testing power pin of integrated chips (ICs) on a printed circuit board.

The storage device 102 may store a variety of information and may be used for various purposes. For example, the storage device 102 may store various programs, applications, user interface functions, and processor functions, for example.

The display 103 may provide a visual output interface between the system 100 and a user. The visual output may include text, graphics, video, and any combination thereof. The display 103 may use liquid crystal display (LCD) technology, or light emitting polymer display (LPD) technology, although other display technologies may be used in other embodiments.

The input device 104 may provide an input interface between the system 100 and a user. The input device 104 may be a keyboard, a mouse or a touch pad, which can be used to input information.

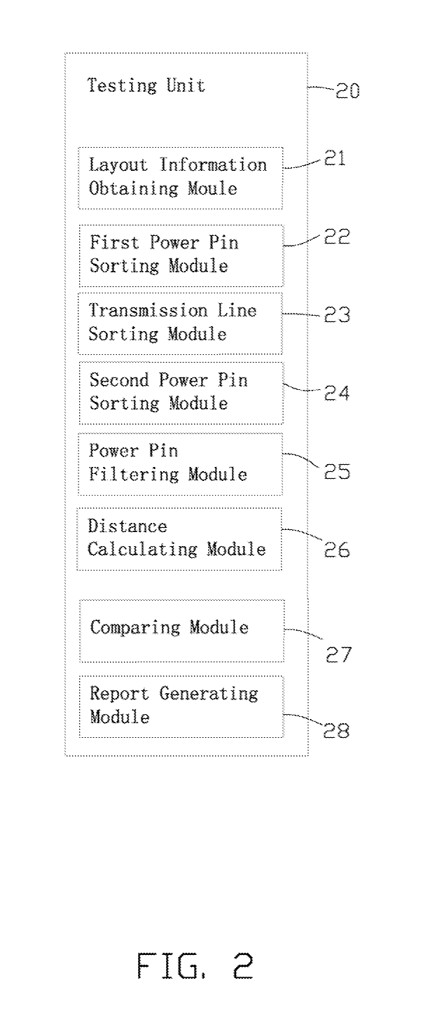

FIG. 2 shows a functional block diagram of one embodiment of the testing unit 20. The testing unit 20 may include a layout information obtaining module 21, a first power pin sorting module 22, a transmission line sorting module 23, a second power pin sorting module 24, a power pin filtering module 25, a distance calculating module 26, a comparing module 27, and a report generating module 28.

The layout information obtaining module 21 may obtain layout information of a printed circuit board. The layout information may include component names, pin names, pin properties, transmission line names, transmission line properties, transmission line positions of the printed circuit board.

The first power pin sorting module 22 can sort power pins having pin properties labeled “power” from a plurality of pins of integrated chips (ICs). Each pin having the pin property labeled “power” is a power pin of each of the ICs that receives power from a power source layer in the printed circuit board.

The transmission line sorting module 23 can sort transmission lines that are connected to the above sorted power pins and are located on outer layers of the printed circuit board.

The second power pin sorting module 24 can sort power pins and ground pins having pin properties labeled “power” and “ground ” of from a plurality of pins of capacities in same transmission line. Each pin having the pin property labeled “power” of is power pin of each capacity that receives power from the power supply in the printed circuit board. Each pin having the pin property labeled “ground” is ground pin of each capacity that is coupled to ground.

The power pin filtering module 25 can filter the power pins from the power pins and the ground pins.

The distance calculating module 26 can calculate distances between the sorted power pins of each IC and the filtered power pins of the capacities and obtain a shortest distance from the distances.

The comparing module 27 can compare the distances with a threshold distance or compare the shortest distance with the threshold distance.

The report generating module 28 can generate a testing report based on a compared result of each of the distances and the threshold distance or generate a testing report based on compare a result of the shortest distance and the threshold distance, to depict whether or not the sorted power pins of the IC are qualified.

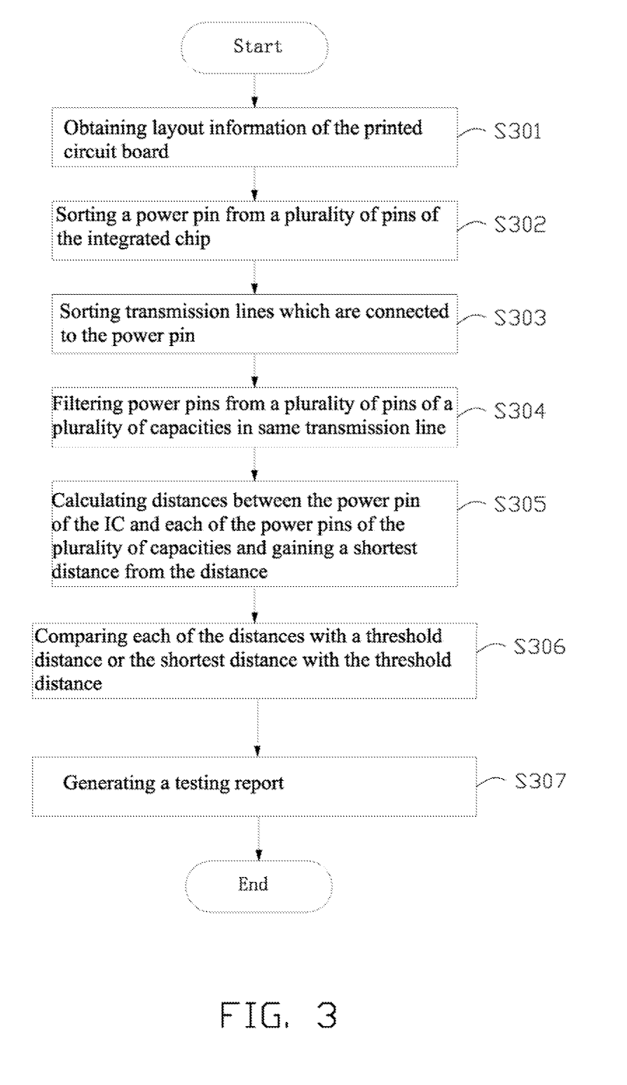

FIG. 3 is a flowchart showing one embodiment of a method for testing a layout of power pins of chipsets on a circuit board. The method comprises the following steps.

In step S301, the layout information obtaining module 21 obtains layout information of a printed circuit board. The layout information can include pin names, pin properties, transmission line names, transmission line properties, transmission line length, and transmission line positions of the layout pattern of the printed circuit board.

In step S302, the first power pin sorting module 22 sorts power pins having pin properties labeled “power” from a plurality of pins of integrated chips (ICs).

In step S303, the transmission line sorting module 23 sorts transmission lines that are connected to the above sorted power pins and are located on outer layers of the printed circuit board.

In step S304, the second power pin sorting module 24 sorts power pins and ground pins having pin properties labeled “power” and “ground ” of from a plurality of pins of capacities in same transmission line.

In step S305, the power pin filtering module 25 filters the power pins from the power pins and the ground pins.

In step S306, the distance calculating module 26 calculates distances between the sorted power pins of each IC and the filtered power pins of the capacities and obtain a shortest distance from the distances.

In step S307, the comparing module 27 compares the distances with a threshold distance or compares the shortest distance with the threshold distance.

In step S308, the report generating module 28 generates a testing report based on a compared result of each of the distances and the threshold distance or generate a testing report based on compare a result of the shortest distance and the threshold distance, to depict whether or not the sorted power pins are qualified

Although numerous characteristics and advantages have been set forth in the foregoing description of embodiments, together with details of the structures and functions of the embodiments, the disclosure is illustrative only, and changes can be made in detail, especially in the matters of arrangement of parts within the principles of the disclosure to the full extent indicated by the broad general meaning of the terms in which the appended claims are expressed.

In particular, depending on the embodiment, certain steps or methods described may be removed, others may be added, and the sequence of steps may be altered. The description and the claims drawn for or in relation to a method may give some indication in reference to certain steps. However, any indication given is only to be viewed for identification purposes, and is not necessarily a suggestion as to an order for the steps.

What is claimed is:

1. A method for testing layout of a power pin of an integrated chip (IC) on a printed circuit board, the method comprising:
obtaining layout information of the printed circuit board;
sorting a power pin from a plurality of pins of the IC based on the layout information;
sorting transmission lines which are connected to the power pin and located on an outer layer of the printed circuit board;
filtering power pins from a plurality of pins of a plurality of capacities in same transmission line;
calculating distances between the power pin of the IC and each of the power pins of the plurality of capacities;
comparing each of the distances with a threshold distance; and
generating a testing report based on a compared result of each of the distances and the threshold distance.

2. The method of claim 1, wherein the layout information includes pin properties, transmission line length, and transmission line positions of the printed circuit board.

3. The method of claim 1, wherein after the step of sorting transmission lines which are connected to the power pin and located on an outer layer of the printed circuit board and before the step of filtering power pins from a plurality of pins of a plurality of capacities in same transmission line, the method further comprises:
sorting power pins and ground pins from the plurality of pins of the plurality of capacities in the same transmission line.

4. The method of claim 1, wherein after the step of calculating distances between the power pin of the IC and each of the power pins of the plurality of capacities and before the step of comparing each of the distances with a threshold distance, the method further comprises:
obtaining a shortest distance from the distances.

5. The method of claim 4, further comprising comparing the shortest distance with a threshold distance.

6. The method of claim 5, further comprising generating the testing report also based on a compared result of the shortest distance and the threshold distance.

7. A system for testing layout of a power pin of an integrated chip (IC) on a printed circuit board, the system comprising:
a layout information obtaining module configured to obtain layout information of the printed circuit board;
a first power pin sorting module configured to sort a power pin from a plurality of pins of the IC based on the layout information;
a transmission line sorting module configured to sort transmission lines which are connected to the power pin and located on an outer layer of the printed circuit board;
a power pin filtering module configured to filter power pins from a plurality of pins of a plurality of capacities in same transmission line;
a distance calculating module configured to calculate distances between the power pin of the IC and each of the power pins of the plurality of capacities;
a comparing module configured to compare each of the distances with a threshold distance; and
a report generating module configured to generate a testing report based on a compared result of each of the distances and the threshold distance.

8. The system of claim 7, wherein the layout information includes pin properties, transmission line length, and transmission line positions of the printed circuit board.

9. The system of claim 7, further comprising a second power pin sorting module, wherein the second power pin sorting module is configured to sort power pins and ground pins from the plurality of pins of the plurality of capacities in the same transmission line.

10. The system of claim 7, wherein the calculating module is configured to obtain a shortest distance from the distances.

11. The system of claim 10, wherein the comparing module is configured to compare the shortest distance with a threshold distance.

12. The system of claim 11, wherein the report generating module is configured to generate the testing report also based on a compared result of the shortest distance and the threshold distance.
